(19) United States
(12) Patent Application Publication
(10) Pub. No.: US 2004/0258256 A1
(43) Pub. Date: Dec. 23, 2004

(54) Amplifier circuit with negative feedback

(76) Inventor: Matthias Ruff, Mannheim (DE)

Correspondence Address: DINSMORE & SHOHL LLP, Suite 500, One Dayton Centre, Dayton, OH, 45402-2023, US

(21) Appl. No.: 10/737,196

(22) Filed: Dec. 16, 2003

(30) Foreign Application Priority Data
Dec. 19, 2002 (DE) 102 59 393.0

(51) Int. Cl. H04R 3/00; H03G 5/00

(52) U.S. Cl. 381/96; 381/98

(57) ABSTRACT

The present invention concerns an amplifier circuit comprising a signal input connection, a power amplifier which amplifies a signal coupled in by way of the signal input connection, a passive frequency divider which divides the signal amplified by the power amplifier into at least two channels, and at least two electroacoustic transducers or at least two output connections for electroacoustic transducers which are each connected to a respective channel made available by the frequency divider. In order to provide an amplifier circuit which manages with only one amplifier upstream of the passive frequency divider, which as far as possible includes no further active components and which nonetheless permits a balanced sound image from the loudspeaker which does justice to even the highest of demands, it is proposed in accordance with the invention that a passive negative feedback is provided between at least one output of the frequency divider and the input of the power amplifier.

### BACKGROUND OF THE INVENTION

The present invention concerns an amplifier circuit and-especially an LF-amplifier (low frequency amplifier) with such an amplifier circuit.

### BRIEF SUMMARY OF THE INVENTION

In particular the present invention concerns an amplifier circuit comprising a signal input connection, a power amplifier which amplifies a signal coupled in by way of the signal input connection, a passive frequency divider which divides the signal amplified by the power amplifier into at least two channels, and at least two electroacoustic transducers or at least two output connections for electroacoustic transducers, which are each connected to a respective channel available from the frequency divider.

The amplifier circuit thus serves for amplifying and transmitting an electrical signal. That electrical signal is then made available to the electroacoustic transducers, for example loudspeakers.

In order to achieve reproduction of the acoustic signal, which is as faithful to the original as possible, it is necessary for the electroacoustic transducers to enjoy a large band width with low levels of linear distortion, short build-up and decay times for pulse-true transmission, advantageous emission properties, low levels of non-linear distortion and a high level of efficiency.

In most cases sound emission of the electroacoustic transducer is effected by a moving diaphragm. The force which permits movement of the diaphragm is produced by the corresponding transducer system. The usual transducer systems include electrodynamic, electrostatic and piezoelectric transducers, wherein the last two are generally used exclusively for tweeters by virtue of the short stroke. Generally relatively large diaphragm areas and/or a large stroke on the part of the diaphragm are necessary for emitting low frequencies.

In principle, in terms of the design of loudspeaker boxes, it is desirable for the loudspeaker overall to cover a frequency range which is as large as possible. That can be effected for example by including a wide-band loudspeaker. As already indicated above however, that generally gives rise to problems as the emission of low frequencies requires a large stroke movement or as an alternative needs large areas for low frequencies while on the other hand the upper limit frequency is restricted by the size of the diaphragm. In the case of simultaneous emission of high- and low-frequency components, Doppler distortion effects can occur, that is to say frequency modulation.

Therefore it is in the meantime usual for the transmission range to be divided to a plurality of loudspeakers. For that purpose the electrical signal is divided by way of a frequency divider into at least two—frequently three—channels which are distinguished by different frequency ranges. Each signal portion or each channel is then connected to its own loudspeaker which can be especially designed for emitting the corresponding frequencies. The use of multichannel loudspeakers generally permits the transmission of a greater frequency spectrum, and a higher load capacity with a lesser tendency to partial oscillations, in which respect fewer intermodulation distortion phenomena and fewer Doppler distortion phenomena occur.

In principle two different actuation methods for the electroacoustic transducers are known. Thus on the one hand there is positive actuation in which the signal coming from the pre-amplifier is amplified in the full frequency spectrum by the final stage and then passed to the loudspeaker. In the loudspeaker the amplified signal is separated by means of a passive frequency divider into the various frequency ranges, such as for example high and low, and passed to the individual electroacoustic transducer systems. Differing levels of efficiency of the individual transducer systems are possibly compensated by means of voltage dividers.

On the other hand, active actuation is known, in which the signal coming from the pre-amplifier is firstly divided in an unamplified condition into the various frequency ranges by means of an electronic active divider and then passed to a respective separate amplifier final stage. It is possible by means of active actuation to effect loudspeaker-specific corrections, such as for example level matching of the individual transducer systems to each other, and suitable filter corrections in the non-amplified signal. In that system, the amplified signals are passed substantially unchanged to the individual electroacoustic transducer systems over lines which are as short as possible.

In the known systems, the systems with active actuation are basically markedly superior to the systems involving passive actuation as the passive frequency divider generally has frequency-dependent characteristics. The passive filters used in the passive frequency divider generally result in volume-dependent characteristics and high loss factors. In addition the individual passive filters displace the phase of the signal to be transmitted, which can result in extinction phenomena and thus collapses in the frequency response characteristic, in particular in the transmission range. The sound image which can be achieved with the known passive systems therefore does not do justice to audiophile demands.

Those disadvantages can be overcome by suitably adapted active actuation. The disadvantage of active actuation lies principally only in the markedly higher cost levels as a plurality of amplifiers have to be used.

In comparison with that state of the art the object of the present invention is to provide an amplifier circuit which makes do with only one amplifier upstream of the passive frequency divider, which as far as possible contains no further active components and which nonetheless permits a balanced sound image from the loudspeaker which does justice to even the highest of demands.

In accordance with the invention that object is attained by an amplifier circuit comprising a signal input connection, a power amplifier which amplifies a signal coupled in by way of the signal input connection, a passive frequency divider which divides the signal amplified by the power amplifier into at least two channels, and at least two electroacoustic transducers or at least two output connections for electroacoustic transducers which are each connected to a respective channel made available by the frequency divider, wherein a passive negative feedback is provided between at least one output of the frequency divider and the power amplifier.

The term passive negative feedback is used to denote that at least one output signal of the passive frequency divider is fed back to the input of the power amplifier, wherein the feedback or negative feedback section contains no active elements. In other words, at least a part of the signal passing through or processed in the amplifier and the frequency divider is fed back to the input of the amplifier. In that situation the signal can either be fed to a non-inverting input in the case of inverting amplifiers, or, in the case of non-inverting amplifiers, it can be fed to an inverting input. The voltage component which is fed back is then superimposed with the currently prevailing signal so that pre-distortion takes place and the distortion phenomena are then reduced by a compensation effect.

In a particularly preferred embodiment the power amplifier is in the form of a differential amplifier with two inputs and the signal input connection is connected to the first input and at least one channel made available by the frequency divider and preferably all channels are respectively connected by way of an ohmic resistor to the second input of the differential amplifier. In this case therefore the negative feedback takes place by way of a suitably designed ohmic connection between the output of the frequency divider and the input of the differential amplifier.

In that respect it is desirable for the resistance values, by way of which the values made available by the frequency divider are connected to the second input of the differential amplifier to be different. That can thus provide for adaptation of the signal made available by the passive frequency divider to the differing levels of efficiency of the individual electroacoustic transducers.

In a further particularly preferred embodiment of the present invention the second input of the differential amplifier is connected to earth by way of an ohmic resistor. That permits matching of the gain of the power amplifier.

Further advantages, features and possible uses of the present invention will be clearly apparent from the description hereinafter of a preferred embodiment and the accompanying drawings.

### BRIEF DESCRIPTION OF THE SEVERAL VIEWS OF THE DRAWINGS

FIG. 1 shows a block circuit diagram of a passive loudspeaker with final stage from the state of the art,

FIG. 2 shows a block circuit diagram of an active loudspeaker with final stage from the state of the art,

FIG. 3 shows a block circuit diagram of an amplifier according to the invention with negative feedback, and

FIG. 4 shows diagrammatic views illustrating the transmission function and the gain factor of the amplifier circuit according to the invention shown in FIG. 3.

### DETAILED DESCRIPTION

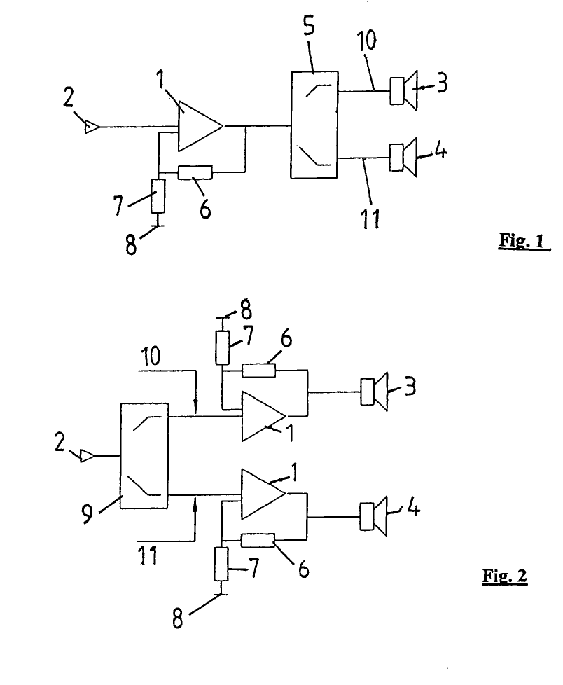

FIG. 1 diagrammatically shows a passive loudspeaker system with final stage, in the form of a block circuit diagram. That system has a signal input connection 2 into which the signal which is to be converted into an acoustic signal is coupled. That signal is firstly passed to a power amplifier (final stage) 1, amplified thereby and then passed to a passive frequency divider 5.

The passive frequency divider divides the input range into a high-frequency branch 10 and a low-frequency branch 11 which are connected to suitably adapted electroacoustic transducers such as for example a tweeter 3 and a woofer 4. The power amplifier 1 is here in the form of a differential amplifier, the output signal being coupled back to the one input of the differential amplifier by way of the resistor 6. That input is additionally connected to earth 8 by way of the resistor 7.

The arrangement shown in FIG. 1 suffers from losses which cannot be disregarded, by virtue of the passive components of the passive divider 5. In addition matching of the levels of the individual channels is possible only with passive resistance networks. Those resistance networks partially convert final stage power into heat. As a result, the transducer has a worse level of efficiency and in addition, due to the ohmic component of the resistance network of the passive divider, the amplifier has a lesser degree of control on the loudspeaker, which is expressed by way of the measure of attenuation factor. The attenuation factor describes the capacity on the part of the amplifier for controlling the diaphragm of the loudspeaker. The amplifier is not only used to drive the loudspeaker, by a current signal being converted into a stroke movement of the diaphragm, but in addition it must also provide for braking decay movements of the diaphragm which possibly occur, when the current is absent. That property is necessary in particular in the case of the woofer 4 as there the stroke movement of the diaphragm is naturally at its greatest.

FIG. 2 shows a block circuit diagram of an active loudspeaker with final stage from the state of the art.

Here the signal input connection 2 is connected directly to an active frequency divider 9 which divides the input signal into a high-frequency signal 10 and a low-frequency signal 11. It is only after the frequency divider that the two channels 10, 11 are amplified by means of the two power amplifiers 1 and then passed directly to the corresponding loudspeakers 3, 4. The individual power amplifiers 1 each have a feedback by way of a respective resistor 6, wherein, in the illustrated embodiment, the two power amplifiers are in the form of differential amplifiers and the one terminal of the differential amplifier 1 is connected to earth 8 by way of the resistor 7. By virtue of suitable dimensioning of the resistors 6 and 7, the level of the individual channels can be matched in a virtually loss-free manner, with the arrangement shown in FIG. 2. If therefore the two loudspeakers 3 and 4 should involve differing levels of efficiency, as is frequently the case in practice, the volumes of the two loudspeakers 3, 4 can be matched to each other by virtue of the dimensioning of the resistors 6 and 7. Practically no insertion losses occur, by virtue of passive components, by using the active frequency divider 9. In addition, a maximum attenuation factor is achieved at the oscillation coils of the electroacoustic transducer 3, 4, as the output of the power amplifiers 1 is connected directly without resistors to the oscillation coils of the electroacoustic transducers.

The arrangement shown in FIG. 2 is therefore superior to the arrangement shown in FIG. 1. It does however suffer from the disadvantage that a plurality of power amplifiers and active components have to be used, which increases the costs and the complexity of this structure.

FIG. 3 shows a particularly preferred embodiment of the present invention. Here, similarly to the arrangement shown in FIG. 1, the input signal is applied by way of the signal input connection 2 to a first connection 12 of a differential amplifier 1. The latter amplifies the signal and makes it available to a passive frequency divider 5 which in turn divides the input signal into a high-frequency signal 10 and a low-frequency signal 11 by means of suitable passive filter elements. The corresponding channels 10, 11 are connected to a tweeter 3 and a woofer 4. Now in accordance with the invention the output signal of the passive frequency divider 5 is fed back by way of suitable resistors R1 and R2 to the second input 13 of the differential amplifier 1. The second input 13 of the differential amplifier is also connected to earth by way of the resistor R3. The resistors R1 and R2 can be so dimensioned that the levels applied to the loudspeakers 3, 4 are matched to the level of efficiency of the respective loudspeakers.

To put this more precisely, the gain of the power amplifier 1 can be adjusted by means of the resistance values R1 and R2. In particular the resistance value R1 determines the gain of the power amplifier in the range of the tweeter and R2 in the range of the woofer.

Expressed mathematically the gain in the tweeter range, with the influence of R2 which is very small being disregarded, with R3<<R2, is as follows:

Gain=(R3+R1)/R3

and in the woofer range with the influence of R1 which is very small being disregarded, with R3<<R1:

Gain=(R3+R2)/R3

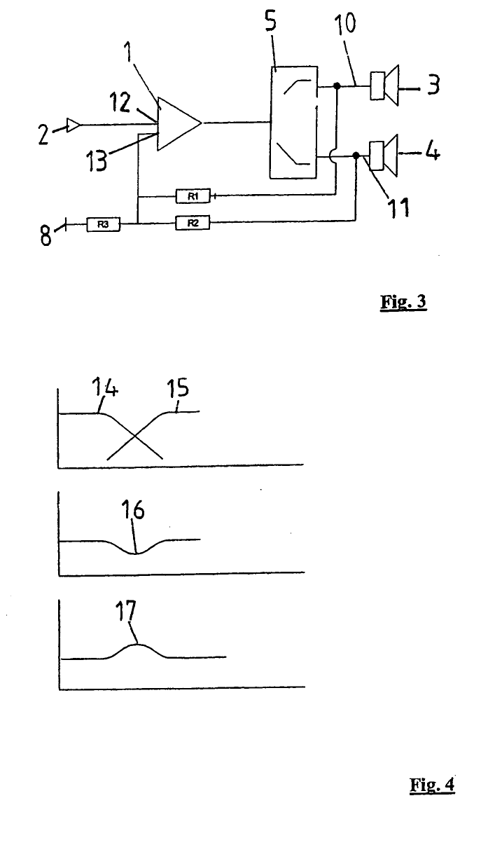

To make this clear FIG. 4 illustrates an example of the regulating characteristics of the LF-amplifier according to the invention with negative feedback after the passive divider.

The uppermost graph in FIG. 4 shows the transmission function of a passive frequency divider. The abscissa shows frequency and the ordinate shows the transmission strength. The passive frequency divider 5 here comprises a high-pass and a low-pass filter. The low-pass transmission function 14 and the high-pass transmission function 15 can be clearly seen. High and low pass are here not matched, that is to say the cut-off frequencies are too far apart.

The central graph in FIG. 4 shows the transmission characteristic of the passive frequency divider. In this case also the frequency is plotted on the abscissa and the transmission strength on the ordinate. It can be clearly seen that, in a central frequency range, the transmission function has a collapse 16, which signifies that only attenuated transmission occurs at those central frequencies. In the embodiment shown in FIG. 1 there would no possibility of correcting that transmission function. As a result therefore the sound image would be unbalanced.

If in contrast a passive divider 5 with the transmission function which is shown in the central graph in FIG. 4 is used in the arrangement according to the invention as shown in FIG. 3, the result of this is that a lower feedback signal is made available at the second input 13 of the differential amplifier 1 for central frequencies by way of the resistors R1 and R2, which in turn involves the consequence that, at central frequencies, the gain of the differential amplifier 1 rises. That is shown by the lower graph in FIG. 4 in which the frequency is again plotted on the abscissa and the gain of the final stage 1 on the ordinate.

It can be clearly seen that the gain rises at central frequencies, as can be seen by the peak 17 on the gain factor. In other words therefore the gain of the differential amplifier 1 is altered by the negative feedback circuit according to the invention without any active elements whatsoever, in such a way that suitable tolerances and mismatchings of the passive components in the passive divider 5 are compensated automatically, that is to say without additional active components being required. Only one single final stage or one single power amplifier 1 is required in the amplifier circuit according to the invention, as in the known passive systems. In addition the use of a passive divider 5 instead of an active divider 9 is less complicated and extravagant and in particular more economical. Possible tolerances and losses in the components of the passive divider can be compensated easily—and in particular without expensive control logic—by the amplifier circuit according to the invention. In particular, the use of suitable passive components in the negative feedback branch can permit matching of both level and also phase of the signal to the corresponding electroacoustic transducer.

In addition the circuit according to the invention compares not only the sum of the output level of the individual channels to the input signal but also the sum of the phase of those channels to the input signal and corrects both errors.

List of References:

1 power amplifier

2 signal input connection

3 tweeter

4 woofer

5 passive frequency divider

6 resistor

7 resistor

8 earth

9 active frequency divider

10 high-frequency signal

11 low-frequency signal

12 first connection

13 second connection

14 low pass transmission function

15 high pass transmission function

16 collapse

17 peak

1. An amplifier circuit comprising a signal input connection, a power amplifier which amplifies a signal coupled in by way of the signal input connection, a passive frequency divider which divides the signal amplified by the power amplifier into at least two channels, and at least two electroacoustic transducers or at least two output connections for electroacoustic transducers which are each connected to a respective channel made available by the frequency divider, wherein a passive negative feedback is provided between at least one output of the frequency divider and the input of the power amplifier.

2. An amplifier circuit according to claim 1 wherein the power amplifieris in the form of a differential amplifier and the signal input connection is connected to the first input of the differential amplifier and at least one channel made available by the frequency divider and preferably all channels are connected by way of a respective ohmic resistor to the second input of the differential amplifier.

3. An amplifier circuit according to claim 2 wherein the resistance values by way of which the channels made available by the frequency divider are connected to the second input of the differential amplifier are different.

4. An amplifier circuit according to claim 2 wherein the second input of the differential amplifier is connected to earth by way of an ohmic resistor.

5. An amplifier circuit according to claim 3 wherein the second input of the differential amplifier is connected to earth by way of an ohmic resistor.

6. A loudspeaker box comprising at least two electroacoustic transducers and an amplifier circuit, wherein said amplifier circuit comprises a signal input connection, a power amplifier which amplifies a signal coupled in by way of the signal input connection, a passive frequency divider which divides the signal amplified by the power amplifier into at least two channels, and at least two electroacoustic transducers or at least two output connections for electroacoustic transducers which are each connected to a respective channel made available by the frequency divider, wherein a passive negative feedback is provided between at least one output of the frequency divider and the input of the power amplifier.

7. A loudspeaker box according to claim 1 wherein the power amplifier is in the form of a differential amplifier and the signal input connection is connected to the first input of the differential amplifier and at least one channel made available by the frequency divider and preferably all channels are connected by way of a respective ohmic resistor to the second input of the differential amplifier.

8. A loudspeaker box according to claim 7 wherein the resistance values by way of which the channels made available by the frequency divider are connected to the second input of the differential amplifier are different.

9. A loudspeaker box according to claim 7 wherein the second input of the differential amplifier is connected to earth by way of an ohmic resistor.

10. A loudspeaker box according to claim 8 wherein the second input of the differential amplifier is connected to earth by way of an ohmic resistor.
